(19) United States
(12) Patent Application Publication
(10) Pub. No.: US 2026/0196119 A1
(43) Pub. Date: Jul. 9, 2026

(54) BATTERY OMISSION PREVENTION STRUCTURE FOR SMOKE DETECTOR

(71) Applicant: Jiangsu Barep Smart Technology Co.,Ltd, Zhangjiagang (CN)

(72) Inventors: Jiangang Chen, Zhangjiagang (CN); Xiaobo Zheng, Zhangjiagang (CN)

(21) Appl. No.: 19/553,510

(22) Filed: Mar. 2, 2026

(30) Foreign Application Priority Data
Feb. 4, 2026 (CN) 202620162507.5

(51) Int. Cl. G08B 17/10; H01M 50/244; H01M 50/251; H05K 5/02; H05K 7/20

(52) U.S. Cl. CPC G08B 17/10; H01M 50/244; H01M 50/251; H05K 5/0208; H05K 5/0247; H05K 7/20127

(57) ABSTRACT

A battery omission prevention structure for a smoke detector is provided, and belongs to the technical field of smoke detectors. The battery omission prevention structure includes: an omission prevention shell, in which an element mounting slot is provided, where a battery compartment is arranged at a bottom of the omission prevention shell; elastic plates are arranged on two sides of the battery compartment; when a battery is not mounted, the elastic plates extend inward and protrude out relative to an inner wall of the battery compartment; tops of the elastic plates extend out of the omission prevention shell; an upper cover clamped onto the omission prevention shell; and a lower cover rotatably clamped onto the omission prevention shell. The following problems are solved: Most smoke detectors are powered by independent batteries. Installation personnel may forget to mount a battery, or may omit mounting a new battery during battery replacement.

### TECHNICAL FIELD

The present disclosure belongs to the technical field of smoke detectors, and in particular, to a battery omission prevention structure for a smoke detector.

### BACKGROUND

A smoke detector is a fire safety device that emits audible and visible alarms in an early stage of a fire by detecting smoke particles in the air. It is a key device for preventing fires and ensuring the life and property safety.

At present, most smoke detectors are powered by independent batteries. When a smoke detector is mounted for the first time and a battery is replaced later, installation personnel may forget to mount a battery, or may omit mounting a new battery during battery replacement. As a result, the power of the equipment is cut off, and the equipment cannot enter a monitoring state, thus posing a significant fire hazard. Meanwhile, the existing battery has an open design. Consequently, the battery may easily accidentally fall off during maintenance and removal. In addition, there are problems that the protection grade is low and the reliability is easily affected due to contact point oxidization and dust intrusion. When an element inside the smoke detector fails, the element needs to be repaired, and the entire smoke detector needs to be disassembled. This affects the repair efficiency.

### SUMMARY

The present disclosure aims to provide a battery omission prevention structure for a smoke detector, to solve the following problems: Most smoke detectors are powered by independent batteries. When a smoke detector is mounted for the first time and a battery is replaced later, installation personnel may forget to mount a battery, or may omit mounting a new battery during battery replacement. As a result, the power of the equipment is cut off, and the equipment cannot enter a monitoring state, thus posing a significant fire hazard. Meanwhile, the existing battery has an open design. Consequently, the battery may easily accidentally fall off during maintenance and removal. In addition, there are problems that the protection grade is low and the reliability is easily affected due to contact point oxidization and dust intrusion. When an element inside the smoke detector fails, the element needs to be repaired, and the entire smoke detector needs to be disassembled. This affects the repair efficiency.

To achieve the above objective, the present disclosure provides the following technical solution: a battery omission prevention structure for a smoke detector, including:

an omission prevention shell, in which an element mounting slot is provided, where a battery compartment is arranged at a bottom of the omission prevention shell; elastic plates are arranged on two sides of the battery compartment; when no battery is mounted, the elastic plates extend inward and protrude out relative to an inner wall of the battery compartment; tops of the elastic plates extend out of the omission prevention shell;

an upper cover clamped onto the omission prevention shell; and

a lower cover rotatably clamped onto the omission prevention shell.

Further, a plurality of buckles are arranged on an inner wall of the element mounting slot. A plurality of clamping bodies are arranged at a bottom of the upper cover. The plurality of clamping bodies are correspondingly clamped onto the plurality of buckles.

Further, the upper cover is provided with a plurality of limiting plates. The omission prevention shell is provided with a plurality of abutting plates. The limiting plates are correspondingly abutted with the abutting plates. The plurality of limiting plates are located on a peripheral side of an element.

Further, the plurality of buckles are spaced apart from each other in a circumferential direction of the inner wall of the element mounting slot.

Further, a plurality of heat dissipation holes are formed in a peripheral side of the omission prevention shell.

Further, a plurality of clamping slot bodies are arranged at the bottom of the omission prevention shell. A plurality of arc-shaped holes are formed in the lower cover. Clamping plates are arranged on inner walls of the arc-shaped holes. The clamping plates are correspondingly clamped onto the clamping slot bodies by rotating the lower cover.

Further, an accommodating slot is further formed in the bottom of the omission prevention shell. The accommodating slot is communicated with the battery compartment. The accommodating slot is located on rear sides of the elastic plates.

Further, when the battery is mounted in place, the elastic plates tilt backward under pressing of the battery. The tops of the elastic plates are not higher than a bottom end surface of the omission prevention shell.

According to the battery omission prevention structure for the smoke detector, which is provided in the present disclosure, the elastic plates are arranged on the two sides of the battery compartment inside the omission prevention shell. The accommodating slot is arranged on the rear sides of the elastic plates. When the battery is not mounted, the elastic plates extend inward and protrude out relative to the inner wall of the battery compartment, and the tops of the elastic plates extend out of the omission prevention shell, so that the lower cover cannot be mounted on the omission prevention shell. When the battery is mounted in place, the elastic plates tilt backward under the pressing of the battery, so that the tops of the elastic plates are not higher than the bottom end surface of the omission prevention shell, and the lower cover can be rotated to clamp the clamping plates onto the clamping slot bodies. This structure can avoid battery omission and eliminate the potential safety hazard. Meanwhile, compared with the open mounting of the battery, this structure has a high protection grade, contact points are not easily oxidized, and dust intrusion hardly occurs. This greatly prolongs the service life of the smoke detector. The upper cover is buckled onto the buckles on the omission prevention shell through the clamping bodies. An electrical element is disposed within the omission prevention shell. When the element is damaged and does not work, only the upper cover is removed from the omission prevention shell, instead of disassembling the entire structure, so that the repair efficiency is greatly enhanced. The limiting plates on the upper cover are abutted with the peripheral side of the element, so that the smoke detector is protected by the internal element while the firmness of the entire structure of the smoke detector is enhanced. The plurality of heat dissipation holes are formed in the peripheral side of the omission prevention shell to cool elements operating inside, thus prolonging the service life.

Therefore, compared with the existing technology, this embodiment has the following technical beneficial effects:

The battery omission prevention structure for the smoke detector solves the following problems: Most smoke detectors are powered by independent batteries. When a smoke detector is mounted for the first time and a battery is replaced later, installation personnel may forget to mount a battery, or may omit mounting a new battery during battery replacement. As a result, the power of the equipment is cut off, and the equipment cannot enter a monitoring state, thus posing a significant fire hazard. Meanwhile, the existing battery has an open design. Consequently, the battery may easily accidentally fall off during maintenance and removal. In addition, there are problems that the protection grade is low and the reliability is easily affected due to contact point oxidization and dust intrusion. When an element inside the smoke detector fails, the element needs to be repaired, and the entire smoke detector needs to be disassembled. This affects the repair efficiency.

### BRIEF DESCRIPTION OF THE DRAWINGS

For clearer descriptions of the technical solutions of the embodiments of the present disclosure, the drawings required to be used in the embodiments are briefly introduced below. It should be understood that the drawings below are only some embodiments of the present disclosure. Therefore, the embodiments shall not be regarded as limitations on the scope. A person of ordinary skill in the art can also obtain other relevant drawings according to these drawings without creative work.

FIG. 1 is a first exploded diagram of a battery omission prevention structure for a smoke detector.

FIG. 2 is a second exploded diagram of a battery omission prevention structure for a smoke detector.

FIG. 3 is a first three-dimensional diagram of an omission prevention shell in a battery omission prevention structure for a smoke detector.

FIG. 4 is a second three-dimensional diagram of an omission prevention shell in a battery omission prevention structure for a smoke detector.

FIG. 5 is a third three-dimensional diagram of an omission prevention shell in a battery omission prevention structure for a smoke detector.

FIG. 6 is a three-dimensional diagram of a battery omission prevention structure for a smoke detector.

### Reference numerals:

1: omission prevention shell; 2: element mounting slot; 3: battery compartment; 4: elastic plate; 5: upper cover; 6: lower cover; 7: buckle; 8: clamping body; 9: limiting plate; 10: abutting plate; 11: heat dissipation hole; 12: clamping slot body; 13: arc-shaped hole; 14: clamping plate; 15: accommodating slot; and 16: battery.

### DETAILED DESCRIPTION OF THE EMBODIMENTS

The technical solutions in the embodiments of the present disclosure are clearly and completely described below with reference to the accompanying drawings in the embodiments of the present disclosure. Apparently, the described embodiments are merely some embodiments of the present disclosure, rather than all of the embodiments. All other embodiments obtained by a person of ordinary skill in the art based on the embodiments of the present disclosure without making creative efforts shall fall within the protection scope of the present disclosure.

To make the objectives, technical solutions, and advantages of the embodiments of the present disclosure clearer, the technical solutions in the embodiments of the present disclosure are clearly described below with reference to the accompanying drawings in the embodiments of the present disclosure. Apparently, the described embodiments are some rather than all of the embodiments of the present disclosure. Components of the embodiments of the present disclosure commonly described and shown in the accompanying drawings here may be arranged and designed in a variety of different configurations.

Therefore, the following detailed descriptions of the embodiments of the present disclosure provided in the accompanying drawings are not intended to limit the scope of the claimed present disclosure, but merely represents selected embodiments of the present disclosure. All other embodiments obtained by a person of ordinary skill in the art based on the embodiments of the present disclosure without making creative efforts shall fall within the protection scope of the present disclosure.

It should be noted that similar reference numerals and letters indicate similar items in the following drawings. Therefore, once a certain item is defined in one drawing, it is unnecessary to further define and explain it in the subsequent drawings.

In the description of the embodiments of the present disclosure, it should be noted that orientations or positional relationships indicated by the terms “upper”, “inner”, and the like are orientations or positional relationships as shown in the drawings or orientations or positional relationships where this invented product is often located during use, and are only for the purpose of facilitating and simplifying the description of the present disclosure instead of indicating or implying that devices or elements indicated need to have particular orientations, and be constructed and operated in the particular orientations, so that these terms are not construed as limiting the present disclosure.

In the description of the present disclosure, it should be noted that unless otherwise explicitly specified or limited, the terms “arrange”, "mount," "connect," and "connection" shall be construed broadly and may be, for example, fixed connection, detachable connection, integrated connection, direct connection, indirect connection via an intermediate, or internal communication between two elements. For those of ordinary skill in the art, the specific meanings of the aforementioned terms in the present disclosure can be understood based on specific conditions.

### Embodiment I:

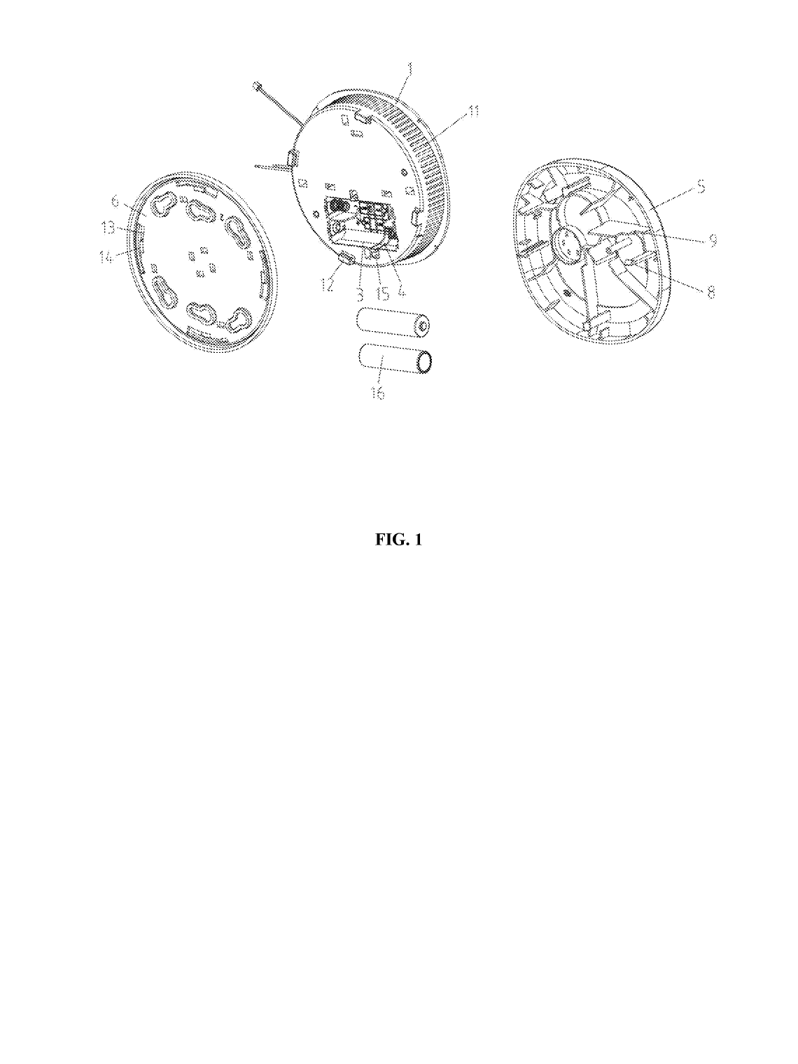

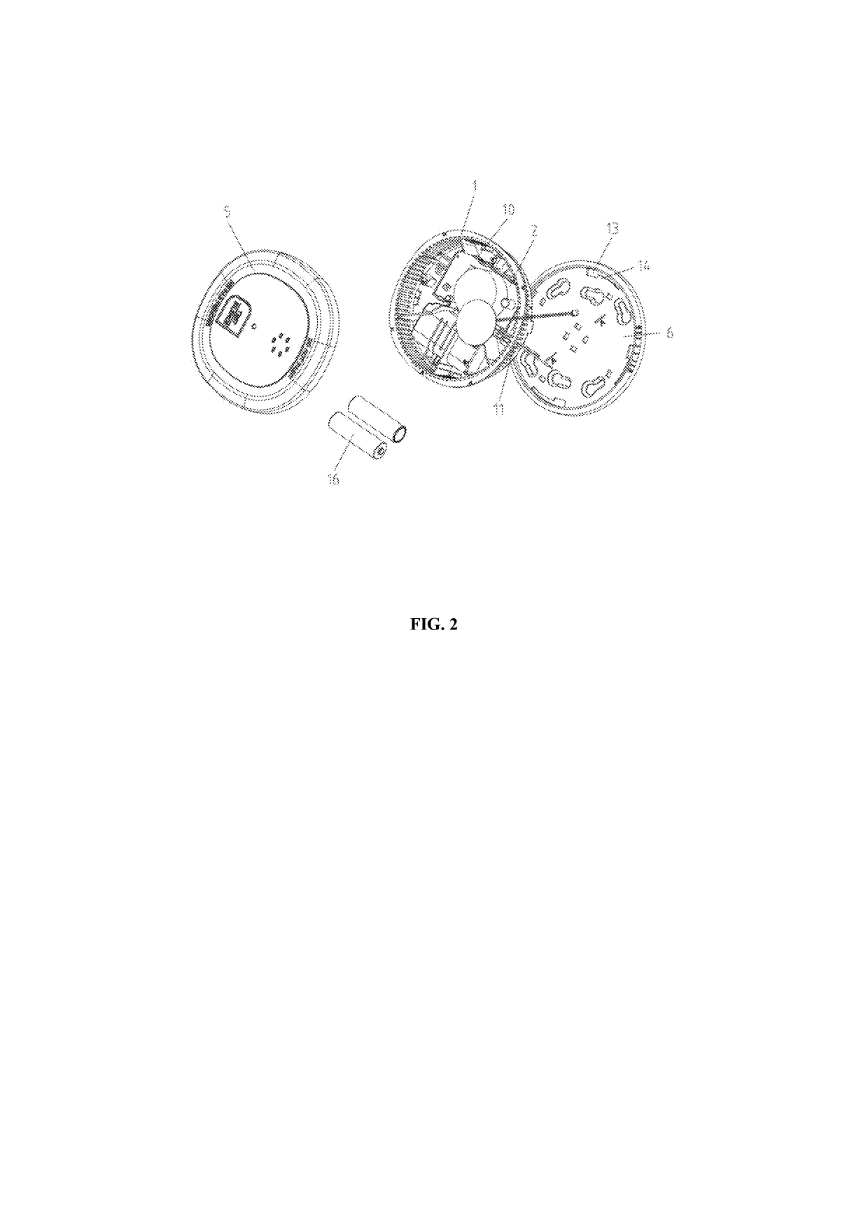

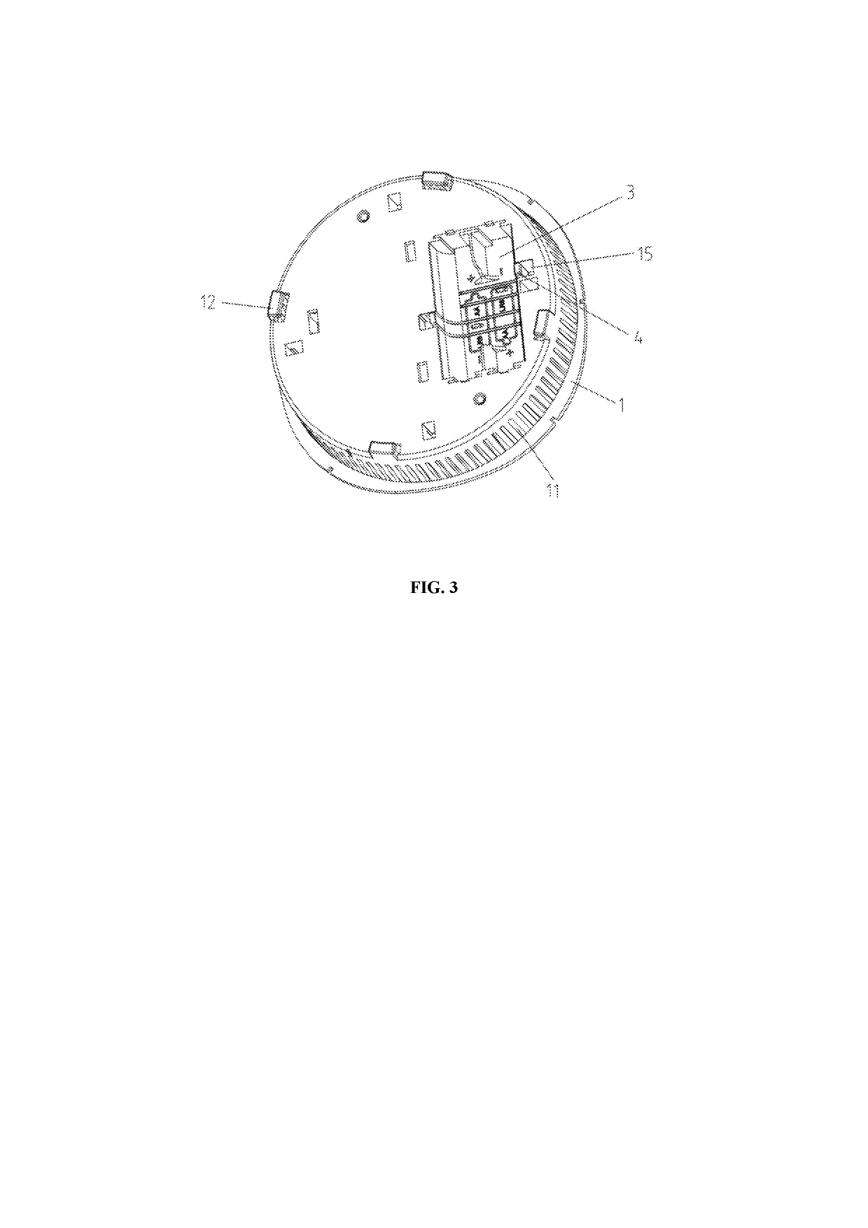

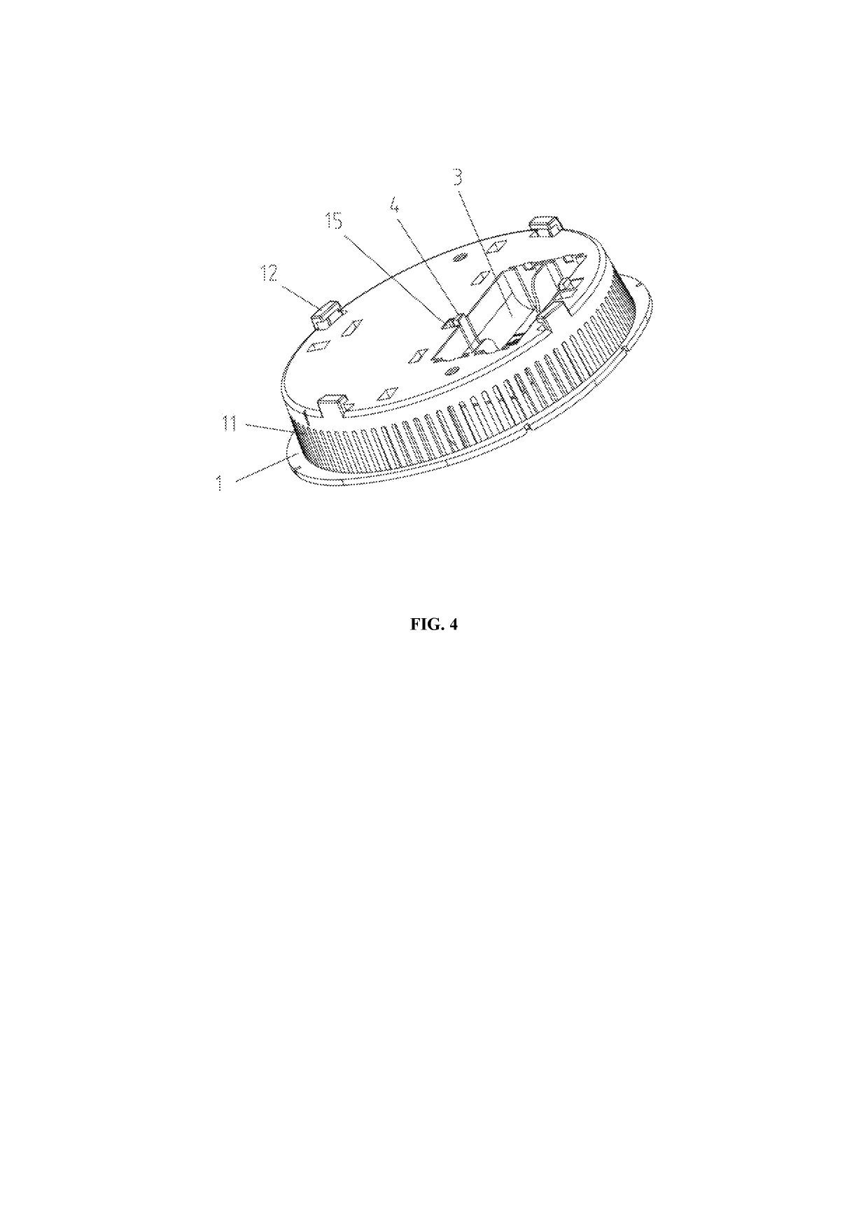

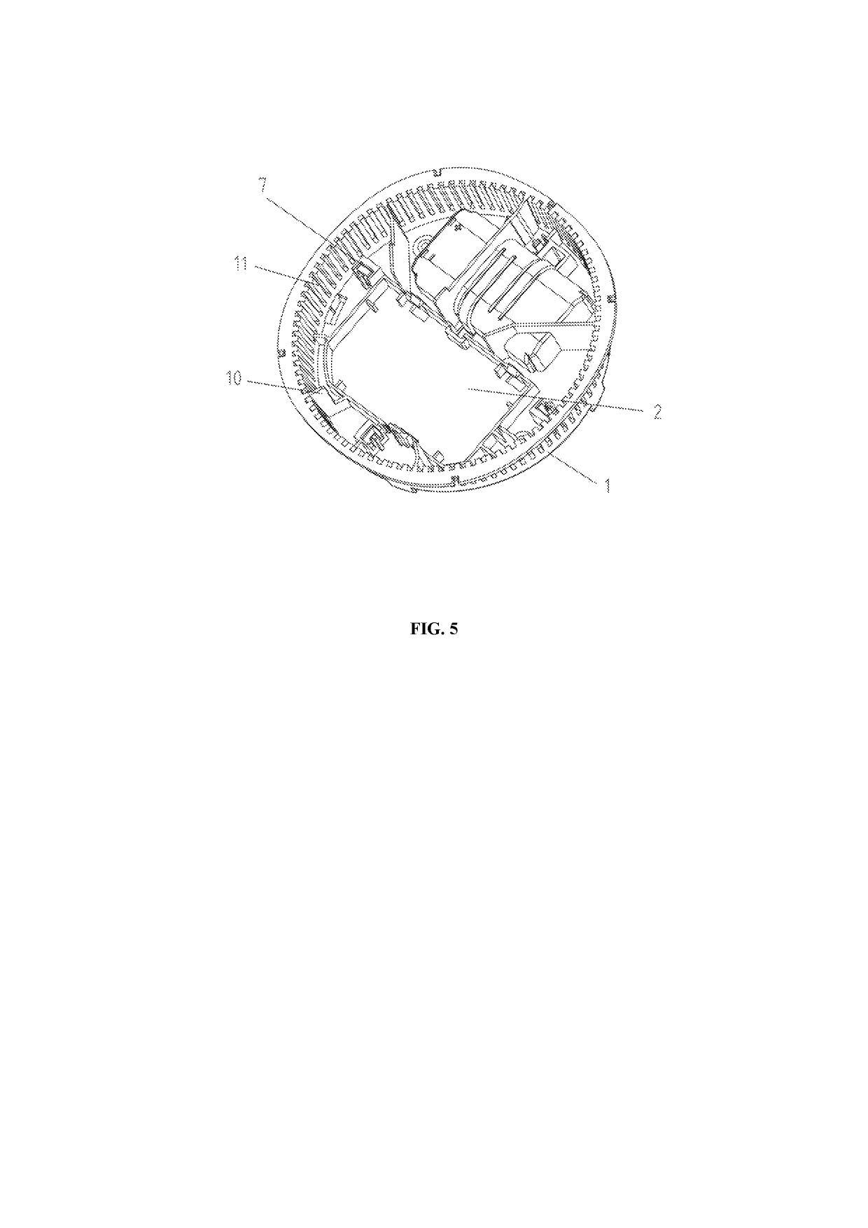

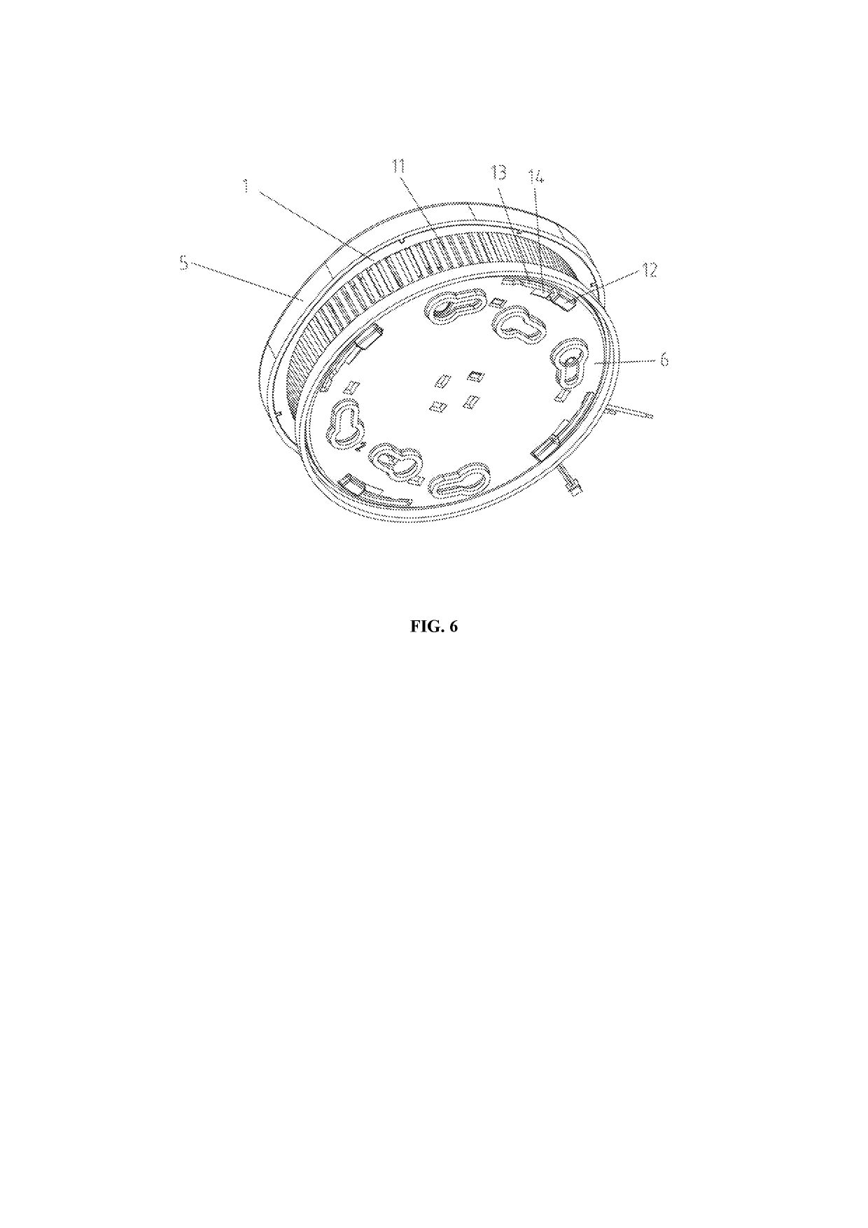

Referring to FIG. 1 to FIG. 6, the present disclosure provides a technical solution: a battery omission prevention structure for a smoke detector, including:

an omission prevention shell 1, in which an element mounting slot 2 is provided, where a battery compartment 3 is arranged at a bottom of the omission prevention shell 1; elastic plates 4 are arranged on two sides of the battery compartment 3; when a battery 16 is not mounted, the elastic plates 4 extend inward and protrude out relative to an inner wall of the battery compartment 3; tops of the elastic plates 4 extend out of the omission prevention shell 1;

an upper cover 5 clamped onto the omission prevention shell 1; and

a lower cover 6 rotatably clamped onto the omission prevention shell 1.

Specifically, referring to FIG. 1 to FIG. 6, a plurality of buckles 7 are arranged on an inner wall of the element mounting slot 2. A plurality of clamping bodies 8 are arranged at a bottom of the upper cover 5. The plurality of clamping bodies 8 are correspondingly clamped onto the plurality of buckles 7.

Specifically, referring to FIG. 1 to FIG. 6, the upper cover 5 is provided with a plurality of limiting plates 9. The omission prevention shell 1 is provided with a plurality of abutting plates 10. The limiting plates 9 are correspondingly abutted with the abutting plates 10. The plurality of limiting plates 9 are located on a peripheral side of an element. This circumferential distribution ensures a balance of force. During assembling, it can achieve a good guiding and aligning effect, prevent component misalignment, and also protect elements.

According to the battery omission prevention structure for the smoke detector, which is provided in the present disclosure, the elastic plates are arranged on the two sides of the battery compartment inside the omission prevention shell. The accommodating slot is arranged on the rear sides of the elastic plates. When the battery is not mounted, the elastic plates extend inward and protrude out relative to the inner wall of the battery compartment, and the tops of the elastic plates extend out of the omission prevention shell, so that the lower cover cannot be mounted on the omission prevention shell. When the battery is mounted in place, the elastic plates tilt backward under the pressing of the battery, so that the tops of the elastic plates are not higher than the bottom end surface of the omission prevention shell, and the lower cover can be rotated to clamp the clamping plates onto the clamping slot bodies. This structure can avoid battery omission and eliminate the potential safety hazard. Meanwhile, compared with the open mounting of the battery, this structure has a high protection grade, contact points are not easily oxidized, and dust intrusion hardly occurs. This greatly prolongs the service life of the smoke detector. The upper cover is buckled onto the buckles on the omission prevention shell through the clamping bodies. An electrical element is disposed within the omission prevention shell. When the element is damaged and does not work, only the upper cover is removed from the omission prevention shell, instead of disassembling the entire structure, so that the repair efficiency is greatly enhanced. The limiting plates on the upper cover are abutted with the peripheral side of the element, so that the smoke detector is protected by the internal element while the firmness of the entire structure of the smoke detector is enhanced. The plurality of heat dissipation holes are formed in the peripheral side of the omission prevention shell to cool elements operating inside, thus prolonging the service life.

Therefore, compared with the existing technology, this embodiment has the following technical beneficial effects:

The battery omission prevention structure for the smoke detector solves the following problems: Most smoke detectors are powered by independent batteries. When a smoke detector is mounted for the first time and a battery is replaced later, installation personnel may forget to mount a battery, or may omit mounting a new battery during battery replacement. As a result, the power of the equipment is cut off, and the equipment cannot enter a monitoring state, thus posing a significant fire hazard. Meanwhile, the existing battery has an open design. Consequently, the battery may easily accidentally fall off during maintenance and removal. In addition, there are problems that the protection grade is low and the reliability is easily affected due to contact point oxidization and dust intrusion. When an element inside the smoke detector fails, the element needs to be repaired, and the entire smoke detector needs to be disassembled. This affects the repair efficiency.

### Embodiment II:

Referring to FIG. 1 to FIG. 6, a battery omission prevention structure for a smoke detector, which is provided in Embodiment II of the present disclosure, is shown. Based on the above embodiment, this embodiment further provides the following improved technical solution: the plurality of buckles 7 are spaced apart from each other in a circumferential direction of the inner wall of the element mounting slot 2.

### Embodiment III:

Referring to FIG. 1 to FIG. 6, a battery omission prevention structure for a smoke detector, which is provided in Embodiment III of the present disclosure, is shown. Based on the above embodiment, this embodiment further provides the following improved technical solution: a plurality of heat dissipation holes 11 are formed in a peripheral side of the omission prevention shell 1.

### Embodiment IV:

Referring to FIG. 1 to FIG. 6, a battery omission prevention structure for a smoke detector, which is provided in Embodiment IV of the present disclosure, is shown. Based on the above embodiment, this embodiment further provides the following improved technical solution: a plurality of clamping slot bodies 12 are arranged at the bottom of the omission prevention shell 1. A plurality of arc-shaped holes 13 are formed in the lower cover 6. Clamping plates 14 are arranged on inner walls of the arc-shaped holes 13. The clamping plates 14 are correspondingly clamped onto the clamping slot bodies 12 by rotating the lower cover 6.

### Embodiment V:

Referring to FIG. 1 to FIG. 6, a battery omission prevention structure for a smoke detector, which is provided in Embodiment V of the present disclosure, is shown. Based on the above embodiment, this embodiment further provides the following improved technical solution: an accommodating slot 15 is further formed in the bottom of the omission prevention shell 1. The accommodating slot 15 is communicated with the battery compartment 3. The accommodating slot 15 is located on rear sides of the elastic plates 4.

### Embodiment VI:

Referring to FIG. 1 to FIG. 6, a battery omission prevention structure for a smoke detector, which is provided in Embodiment VI of the present disclosure, is shown. Based on the above embodiment, this embodiment further provides the following improved technical solution: when the battery 16 is mounted in place, the elastic plates 4 tilt backward under pressing of the battery 16. The tops of the elastic plates 4 are not higher than a bottom end surface of the omission prevention shell 1. This avoids battery omission and avoids a potential hazard of fire detection.

The above is only the specific implementation of the present disclosure, but the protection scope of the present disclosure is not limited to this. Equivalent replacements or changes made by any person skilled in the art within the technical scope disclosed in the present disclosure based on the technical solutions and concept of the present disclosure shall all fall within the protection scope of the present disclosure.

What is claimed is:

1. A battery omission prevention structure for a smoke detector, comprising:
an omission prevention shell (1), in which an element mounting slot (2) is provided, wherein a battery compartment (3) is arranged at a bottom of the omission prevention shell (1); elastic plates (4) are arranged on two sides of the battery compartment (3); when a battery (16) is not mounted, the elastic plates (4) extend inward and protrude out relative to an inner wall of the battery compartment (3); tops of the elastic plates (4) extend out of the omission prevention shell (1);
an upper cover (5) clamped onto the omission prevention shell (1); and
a lower cover (6) rotatably clamped onto the omission prevention shell (1).

2. The battery omission prevention structure for the smoke detector according to claim 1, wherein a plurality of buckles (7) are arranged on an inner wall of the element mounting slot (2); a plurality of clamping bodies (8) are arranged at a bottom of the upper cover (5); and the plurality of clamping bodies (8) are correspondingly clamped onto the plurality of buckles (7).

3. The battery omission prevention structure for the smoke detector according to claim 1, wherein the upper cover (5) is provided with a plurality of limiting plates (9); the omission prevention shell (1) is provided with a plurality of abutting plates (10); the limiting plates (9) are correspondingly abutted with the abutting plates (10); and the plurality of limiting plates (9) are located on a peripheral side of an element.

4. The battery omission prevention structure for the smoke detector according to claim 2, wherein the plurality of buckles (7) are spaced apart from each other in a circumferential direction of the inner wall of the element mounting slot (2).

5. The battery omission prevention structure for the smoke detector according to claim 1, wherein a plurality of heat dissipation holes (11) are formed in a peripheral side of the omission prevention shell (1).

6. The battery omission prevention structure for the smoke detector according to claim 1, wherein a plurality of clamping slot bodies (12) are arranged at the bottom of the omission prevention shell (1); a plurality of arc-shaped holes (13) are formed in the lower cover (6); clamping plates (14) are arranged on inner walls of the arc-shaped holes (13); and the clamping plates (14) are correspondingly clamped onto the clamping slot bodies (12) by rotating the lower cover (6).

7. The battery omission prevention structure for the smoke detector according to claim 1, wherein an accommodating slot (15) is further formed in the bottom of the omission prevention shell (1); the accommodating slot (15) is communicated with the battery compartment (3); and the accommodating slot (15) is located on rear sides of the elastic plates (4).

8. The battery omission prevention structure for the smoke detector according to claim 1, wherein when the battery (16) is mounted in place, the elastic plates (4) tilt backward under pressing of the battery (16); and the tops of the elastic plates (4) are not higher than a bottom end surface of the omission prevention shell (1).
